(19) United States
(12) Patent Application Publication
(10) Pub. No.: US 2025/0221042 A1
(43) Pub. Date: Jul. 3, 2025

(54) DISPLAY PANEL AND DISPLAY DEVICE

(71) Applicants: Wuhan Tianma MicroElectronics Co., Ltd. Shanghai Branch., Shanghai (CN); Wuhan Tianma Micro-Electronics Co., Ltd., Wuhan (CN)

(72) Inventors: Huiping CHAI, Shanghai (CN); Lin ZHANG, Shanghai (CN)

(21) Appl. No.: 18/676,228

(22) Filed: May 28, 2024

(30) Foreign Application Priority Data
Jan. 2, 2024 (CN) 202410005072.9

(51) Int. Cl. H01L 27/12; H01L 25/16

(52) U.S. Cl. CPC H10D 86/60; H01L 25/167; H10D 86/441

(57) ABSTRACT

A display panel and a display device are provided. The display panel includes a substrate plate; light-emitting elements and pixel driving circuits electrically connected to the light-emitting elements; first power signal lines electrically connected to the pixel driving circuits; and second power signal lines. The second power signal lines and the first power signal lines are located in a first conductor layer and have substantially same line shapes.

### CROSS-REFERENCE TO RELATED APPLICATION

This application claims the priority of Chinese Patent Application No. 202410005072.9, filed on Jan. 2, 2024, the content of which is incorporated herein by reference in its entirety.

### TECHNICAL FIELD

The present disclosure generally relates to the field of display technology and, more particularly, relates to a display panel and a display device.

### BACKGROUND

There are usually a plurality of types of signal lines in a display panel. Each type of signal lines is electrically connected to circuit elements in pixel driving circuits and transmits electrical signals provided by driving chips, to control a light-emitting element to emit light, thereby enabling the display panel to display images.

The pixel driving circuits in the display panel are usually arranged in an array, such that distances between the pixel driving circuits and the driving chips at different locations in the display panel are not exactly the same. Since the signal lines are connected between the pixel driving circuits and the driving chips and the signal lines themselves have resistance, the voltage drop on the signal lines at different positions is different, resulting in electrical signals received by the pixel driving circuits at different positions of the display panel having different amplitudes. Therefore, the display panel has a poor display uniformity, limiting the further improvement of pixels per inch (PPI).

### SUMMARY

One aspect of the present disclosure provides a display panel. The display panel includes a substrate plate; light-emitting elements; pixel driving circuits electrically connected to the light-emitting elements; first power signal lines electrically connected to the pixel driving circuits; and second power signal lines. The second power signal lines and the first power signal lines are located in a first conductor layer and have substantially same line shapes.

Another aspect of the present disclosure provides a display device. The display device includes a display panel. The display panel includes a substrate plate; light-emitting elements; pixel driving circuits electrically connected to the light-emitting elements; first power signal lines electrically connected to the pixel driving circuits; and second power signal lines. The second power signal lines and the first power signal lines are located in a first conductor layer and have substantially same line shapes.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates an exemplary pixel driving circuit consistent with various disclosed embodiments in the present disclosure;

FIG. 2 illustrates an exemplary control timing diagram consistent with various disclosed embodiments in the present disclosure;

FIG. 3 illustrates a top view of film layer structures of a display panel;

FIG. 4 illustrates a top view of film layer structures of an exemplary display panel consistent with various disclosed embodiments in the present disclosure;

FIG. 5 illustrates a top view of film layer structures of another exemplary display panel consistent with various disclosed embodiments in the present disclosure;

FIG. 6 illustrates a top view of film layer structures of another exemplary display panel consistent with various disclosed embodiments in the present disclosure;

FIG. 7 illustrates a top view of film layer structures of another exemplary display panel consistent with various disclosed embodiments in the present disclosure;

FIG. 8 illustrates a top view of film layer structures of another exemplary display panel consistent with various disclosed embodiments in the present disclosure;

FIG. 9 illustrates a top view of film layer structures of another exemplary display panel consistent with various disclosed embodiments in the present disclosure;

FIG. 10 illustrates a top view of film layer structures of another exemplary display panel consistent with various disclosed embodiments in the present disclosure;

FIG. 11 illustrates a top view of film layer structures of another exemplary display panel consistent with various disclosed embodiments in the present disclosure;

FIG. 12 illustrates a top view of film layer structures of another exemplary display panel consistent with various disclosed embodiments in the present disclosure;

FIG. 13 illustrates a top view of film layer structures of another exemplary display panel consistent with various disclosed embodiments in the present disclosure;

FIG. 14 illustrates a top view of film layer structures of another exemplary display panel consistent with various disclosed embodiments in the present disclosure;

FIG. 15 illustrates a top view of film layer structures of another exemplary display panel consistent with various disclosed embodiments in the present disclosure;

FIG. 16 illustrates a top view of film layer structures of another exemplary display panel consistent with various disclosed embodiments in the present disclosure;

FIG. 17 illustrates a top view of film layer structures of another exemplary display panel consistent with various disclosed embodiments in the present disclosure;

FIG. 18 illustrates a structure of an exemplary display panel consistent with various disclosed embodiments in the present disclosure;

FIG. 19 illustrates a structure of another exemplary display panel consistent with various disclosed embodiments in the present disclosure; and

FIG. 20 illustrates a structure of an exemplary display device consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted.

Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, relational terms such as first and second are only used to distinguish one entity or operation from another entity or operation, and do not necessarily require or imply any such actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or region is referred to as being “on” or “above” another layer or another region, the layer or region may be directly on the other layer or region, or indirectly on the other layer or region, for example, layers/components between the layer or region and another layer or another region. And, for example, when the component is reversed, the layer or region may be “below” or “under” the other layer or region. In the present disclosure, the term “electrical connection” refers to that two components are directly electrically connected with each other, or the two components are electrically connected via one or more other components.

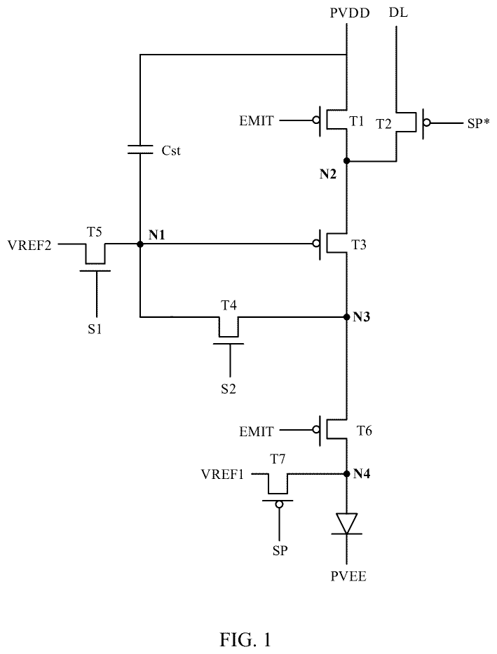

FIG. 1 is a structure of an exemplary pixel driving circuit provided by the present disclosure. The circuit in FIG. 1 is a 7T1C pixel driving circuit. “T” represents a transistor, “7T” represents a total of 7 transistors in the pixel driving circuit, “C” represents a storage capacitor, and “1C” represents a total of 1 storage capacitor in the pixel driving circuit.

The pixel driving circuit may include a power writing transistor T1, a data writing transistor T2, a driving transistor T3, a compensation transistor T4, a second reset transistor T5, a light-emitting control transistor T6, a first reset transistor T7, and a storage capacitor Cst. The power writing transistor T1, the data writing transistor T2, the driving transistor T3, the light-emitting control transistor T6 and the first reset transistor T7 may be P-type transistors. The compensation transistor T4 and the second reset transistor T5 may be N-type transistors. The connection relationship between each transistor and the storage capacitor is shown in FIG. 1, which will not be described in detail here. The pixel driving circuit is electrically connected to a corresponding light-emitting element, and the light-emitting diode in the figure represents the light-emitting element. It should be noted that in the pixel driving circuit provided by the embodiments of the present disclosure, the specific type of transistors is not limited and may be selected according to the actual situation.

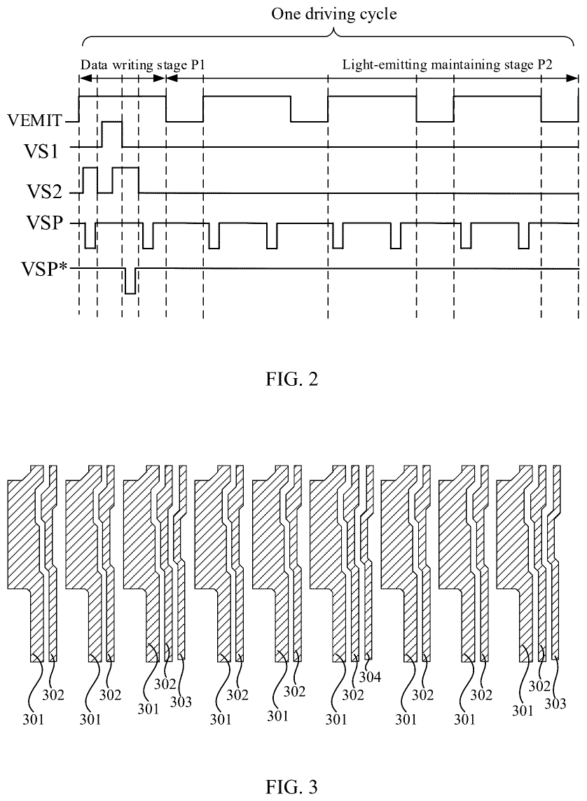

FIG. 2 is a schematic diagram of timing control provided by an embodiment of the present disclosure. For a working process of the pixel driving circuit, for example, as shown in FIG. 1 and FIG. 2, a first scanning signal VS1 of a S1 signal line may control turn-on or turn-off of the second reset transistor T5 of the pixel driving circuit, and may reset the potential of the gate of the driving transistor T3 when the second reset transistor T5 is turned on, that is, a second reset signal of a VREF2 signal line may be transmitted to the second reset transistor T5 and reset a connection node (a first node N1) of the driving transistor T3, the second reset transistor T5, the compensation transistor T4 and the storage capacitor Cst. A third scanning signal VSP* of a SP* signal line may control turn on or turn off of the data writing transistor T2 of the pixel driving circuit, and, when the data writing transistor T2 is turned on, a data signal of a DL signal line may be written to the gate of driving transistor T3. A second scanning signal VS2 of an S2 signal line may control turn on and turn off of the compensation transistor T4, and compensate the threshold voltage of the driving transistor T3 when the compensation transistor T4 is turned on. At the same time, the SP signal line may control turn on and turn off of the first reset transistor T7, and reset the anode of the light-emitting element connected to the pixel driving circuit when the first reset transistor T7 is turned on, that is, the first reset signal of the VREF1 signal line may be transmitted to the anode of the light-emitting element. The light-emitting control scan signal VEMIT of the EMIT signal line may control turn on and turn off of the power writing transistor T1 and the light-emitting control transistor T6, and the first power signal of the PVDD signal line may be transmitted to the light-emitting element when the power writing transistor T1 and the second light-emitting control transistor T6 are turned on, thereby realizing display and emitting light of the light-emitting element.

Pixel driving circuits may be arranged in an array in a display panel. Taking the VREF1 signal line as an example, when the VREF1 signal line outputs a corresponding first reset signal, the first reset signal may be sequentially transmitted to the first reset transistors T7 in the pixel driving circuits of each row. However, because of the long distance between the first reset transistors T7 in some pixel driving circuits and the signal source of the VREF1 signal line, and the certain resistance of the VREF1 signal line itself, the first reset signal may have a certain voltage drop and the voltages of the first reset signals received by the first reset transistors T7 may be different. Therefore, the display effects of each light-emitting element electrically connected and controlled by each pixel driving circuit may be different, and the uniformity of the display panel may be poor. At least some of the other signal lines (such as the PVEE signal line) are similar in principle to the above-mentioned VREF1 signal line, and will not be described again here.

FIG. 3 is a top view of the film layer structure of a display panel in existing technologies. As shown in FIG. 3, in existing technologies, some wires that are originally used as reference power signal lines (corresponding to the VREF signal line in FIG. 1, including at least one of the VREF1 signal line and VREF2 signal line) are set as common power signal lines (corresponding to the PVEE signal line in FIG. 1), to improve the display uniformity of the display panel. Wires corresponding to 301 represent the PVDD signal lines in FIG. 1, wires corresponding to 302 represent the DL signal lines in FIG. 1, wires corresponding to 303 are the reference power signal lines which represent the VREF signal lines in FIG. 1, and wires corresponding to 304 is the common power signal lines which represent the PVEE signal lines in FIG. 1. As shown in FIG. 3, the uniformity of the PVEE signal in the display panel is improved, thereby improving the uniformity of the display panel.

However, the PPI of existing display panels is getting larger and larger. Correspondingly, pitches between pixel driving circuits are getting smaller and smaller. Moreover, existing technologies have higher requirements for display uniformity of display panels. Additional wires disposed between pixel driving circuits will affect the pitches and PPI of the pixel driving circuits. Therefore, how to improve the uniformity of the display panel while ensuring the PPI and pitches of the display panel has become a difficult problem.

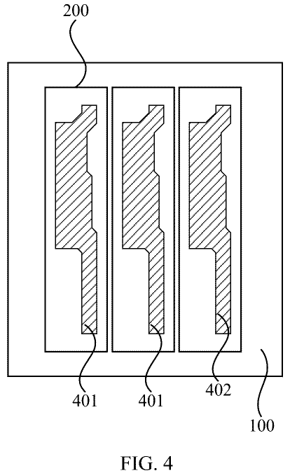

The present disclosure provides a display panel and a display device to at least partially alleviate the above problem. The present disclosure provides a display panel. In one embodiment shown in FIG. 4 which is a top view of a film layer structure of a display panel, the display panel may include: a substrate plate 100, light-emitting elements and pixel driving circuits 200 where the pixel driving circuits 200 are electrically connected to the light-emitting elements, first power signal lines 401 electrically connected to the pixel driving circuits 200, and second power signal lines 402. The second power signal lines 402 and the first power signal lines 401 may be located in a first conductor layer, and may have roughly same line shapes.

As shown in FIG. 4, in one embodiment, one light-emitting element may be a functional element capable of emitting a specific color, such as a light-emitting diode, and so on. One pixel driving circuit 200 may be a functional element that is electrically connected to one corresponding light-emitting element and control whether the corresponding light-emitting element emits light and/or the duration of light-emitting based on a received electrical signal. The pixel driving circuit 200 may be a 7T1C pixel driving circuit 200 shown in FIG. 1, or another type of pixel driving circuit 200, such as an 8T1C pixel driving circuit 200, a 7T2C pixel driving circuit 200, etc. It will not be elaborated or limited here. The electrical signals described in the embodiments of the present disclosure are the general name of the signals in all the signal lines in the embodiments of the present disclosure. One first power signal line 401 may be a signal line that is electrically connected to one corresponding pixel driving circuit 200 and may provide a first power signal to the corresponding pixel driving circuit 200, such as one PVDD signal line in FIG. 1. One second power signal line 402 may be a signal line electrically connected to one corresponding pixel driving circuit 200 or one corresponding light-emitting element, and the electrical signal corresponding to the second power signal line 402 may be able to affect the display uniformity of the display panel. The line types of the second power signal lines 402 and the first power signal lines 401 may include shape parameters, spatial positions, functional settings, etc. of conductors used as the first power signal lines 401 and the second power signal lines 402, such as length, width, shape, distribution area, design functions that are able to be realized, etc, of conductors. As shown in FIG. 4, the line shapes of the first power signal lines 401 and the second power signal lines 402 may be generally the same (including cases where they are completely identical or there are expected slight differences), and the line shapes of the first power signal lines 401 and the data signal lines may be different. The data signal lines may correspond to the signal lines DL in FIG. 1.

In terms of appearance parameters and spatial position, the second power signal lines 402 and the first power signal lines 401 may have substantially the same line shapes, may mean the same within the allowable error range.

To solve the problem of small pitches in the display panel and high requirements for display uniformity of the display panel, in the present disclosure, wires originally prepared from the first conductor layer as the first power signal lines 401 may be used as the second power signal lines 402. The number of wirings of the second power signal lines 402 may be increased and the voltage drop differences of the second power signal lines 402 at different positions in the display panel may be reduced, thereby improving the display uniformity of the display panel. Further, since the uniformity of the display panel may be improved without adding additional wires to the display panel, other wiring settings may not be affected and new structures may not be added, which may be beneficial to ensuring the overall design and ensuring that the manufacturing difficulty and cost of the display panel are not increased. Also, additional space between the pixel driving circuits 200 may not be occupied, which may be beneficial to reducing the pitches between the pixel driving circuits 200 and improving the PPI of the display panel.

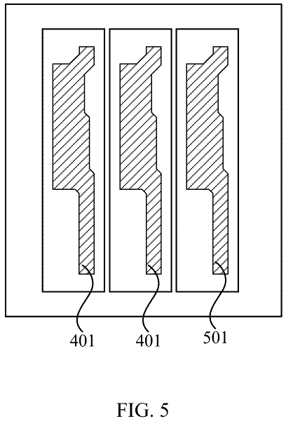

In some embodiments shown in FIG. 5 which is a top view of a film layer structure of another display panel, the second power signal lines may at least include common power signal lines 501. The common power signal lines 501 may be electrically connected to the light-emitting elements.

The common power signal lines 501 may be the PVEE signal lines in FIG. 1, and the common power signal lines 501 may be electrically connected to the cathodes of the light-emitting elements.

In the present embodiment of the present disclosure, wires originally used as the PVDD signal lines may be changed into the common power signal lines 501. The common power signal lines 501 may have substantially the same line shape as the first power signal lines 401. After being used as the common power signal lines 501, the number of common power signal lines 501 may be increased, reducing the voltage drop of the electrical signals on the common power signal lines 501 at different positions in the display panel and improving the uniformity of the display panel. Further, no more wiring may be required in the above embodiments, so other wiring settings may be not affected and no new structure may need to be added, which is conducive to ensuring that the overall design and reducing the production difficulty and the cost of the display panel. Also, the pitches between the pixel driving circuits 200 may not be increased, which is beneficial to improving the PPI of the display panel.

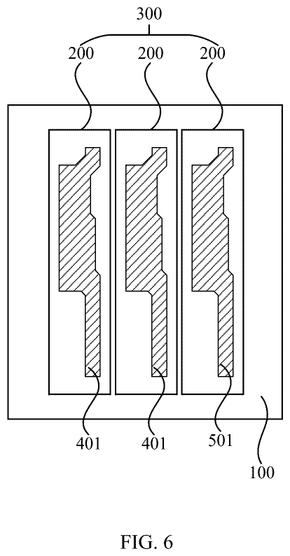

In some embodiments shown in FIG. 6 which is a top view of a film layer structure of another display panel, at least three pixel driving circuits 200 may form a pixel driving circuit group 300. In one same pixel driving circuit group 300, different pixel driving circuits 200 may be electrically connected to light-emitting elements with different colors respectively. Along a direction perpendicular to a plane where the substrate plate 100 is located, different pixel driving circuits 200 in one same pixel driving circuit group 300 may overlap different power signal lines respectively. Among at least three power signal lines corresponding to one same pixel driving circuit group 300, at least one power signal line may be the first power signal line 401, and at least another power signal line may be the common power signal line 501.

For example, in one embodiment shown in FIG. 6, three pixel driving circuits 200 may form one pixel driving circuit group 300, and the three pixel driving circuits 200 may be electrically connected to a red light-emitting element, a green light-emitting element, and a blue light-emitting element respectively. The present disclosure has no limit the the order of the light-emitting elements with different colors. For description purposes only, the embodiment shown in FIG. 6 where three pixel driving circuits 200 form one pixel driving circuit group 300 is used as an example to illustrate the present disclosure, and does not limit the scopes of the present disclosure. In some other embodiments, more than three pixel driving circuits 200 may form one pixel driving circuit group 300.

In one embodiment, for each pixel driving circuit group 300, at least one power signal line may be used as the common power signal line 501, and at least one power signal line may be used as the first power signal line 401. In the embodiment shown in FIG. 6, two of the three power signal lines may be exemplarily used as the first power signal lines 401 and the remaining one may be used as the common power signal line 501. The common power signal line 501 may be a second power signal line.

In the present embodiment of the present disclosure, the voltage drop of the common power signal in the common power signal lines 501 of the pixel driving circuits 200 at different positions in the display panel may be reduced based on the common power signal lines 501, thereby improving the uniformity of the display panel. Further, since no new wiring is added, the pitches between the pixel driving circuits 200 of the display panel may not be affected, ensuring that the pitches of the display panel will not be increased. The PPI of the display panel may be improved.

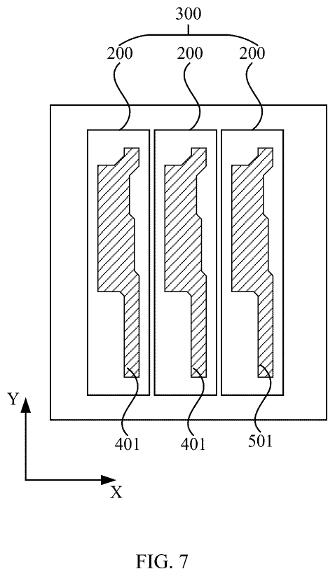

In some embodiments shown in FIG. 7 which is a top view of a film layer structure of another display panel, the power signal lines may extend along a first direction. Among the at least three power signal lines corresponding to one same pixel driving circuit group 300, at least two power signal lines adjacent along a second direction may both be the first power signal lines 401, and at least one other power signal line may be a common power signal line 501. The second direction may intersect the first direction.

In FIG. 7, the Y direction may be the first direction, the X direction may be the second direction, and the first direction and the second direction may be perpendicular to each other. A plane formed by the first direction and the second direction may be parallel to or coincident with the plane of the display panel. In the embodiment shown in FIG. 7, three pixel driving circuits 200 may form one pixel driving circuit group 300, two adjacent power signal lines among the power signal lines arranged in order along the second direction may be used as the first power signal lines 401 and the remaining one power signal line may serve as the second power signal line 402.

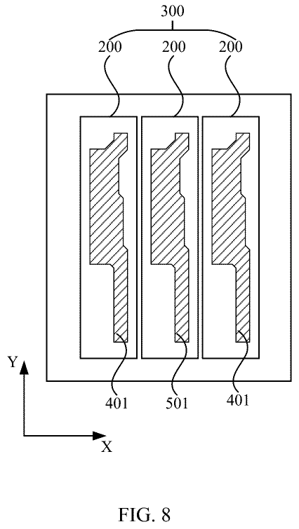

In some embodiments shown in FIG. 8 which is a top view of a film layer structure of another display panel, among the at least three power signal lines corresponding to one same pixel driving circuit group 300, at least one power signal line may be a common power signal line 501 located between two power signal lines that are the first power signal lines 401 along the second direction. The common power signal line 501 may be a second power signal line.

In FIG. 8, the Y direction may be the first direction, the X direction may be the second direction, and the first direction and the second direction may be perpendicular to each other. A plane formed by the first direction and the second direction may be parallel to or coincident with the plane of the display panel. In the present embodiment, one power signal line located between two power signal lines among the power signal lines arranged in order along the second direction may be used as the common power signal line 501, and power signal lines on both sides of the common power signal line 501 may serve as the first power signal lines 401. In some other embodiment, one pixel driving circuit group 300 may include more pixel driving circuits 200 and may be similar to the embodiments in FIG. 7 or FIG. 8.

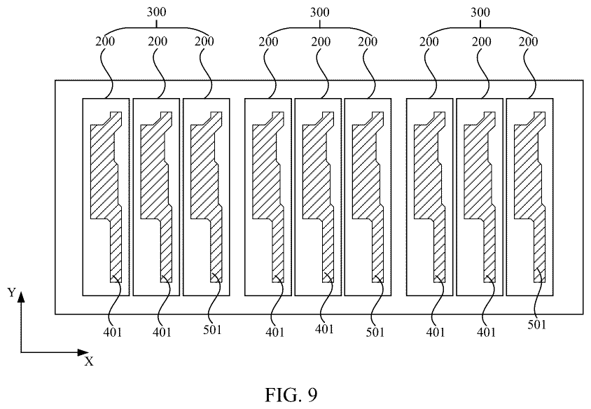

In some embodiments shown in FIG. 9 which is a top view of a film layer structure of another display panel, at least three pixel driving circuits 200 may form one pixel driving circuit group 300. Different pixel driving circuits 200 in one same pixel driving circuit group 300 may be electrically connected to light-emitting elements of different colors respectively. The first power signal lines 401 and the common power signal lines 501 may extend along the first direction. Along the second direction, each pixel driving circuit group 300 may be provided with a corresponding common power signal line 501. The common power signal lines 501 may be the second power signal lines.

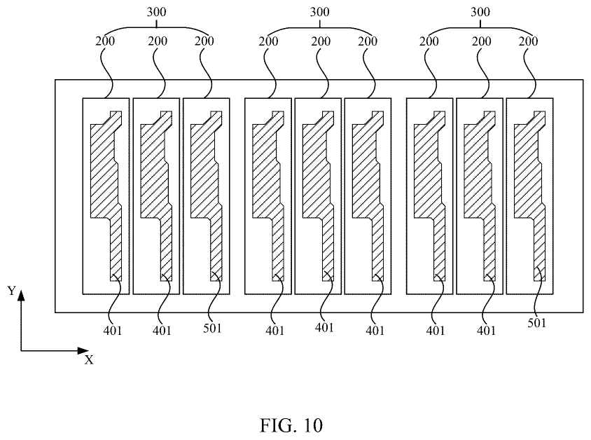

In some embodiments shown in FIG. 10 which is a top view of a film layer structure of another display panel, at least three pixel driving circuits 200 may form one pixel driving circuit group 300. Different pixel driving circuits 200 in one same pixel driving circuit group 300 may be electrically connected to light-emitting elements of different colors respectively. The first power signal lines 401 and the common power signal lines 501 may extend along the first direction. One common power signal line 501 may be provided at every interval of N1 pixel driving circuit groups 300, where N1 may be an integer larger than 0 and the second direction may intersect the first direction. The common power signal lines 501 may be the second power signal lines.

In FIG. 9 and FIG. 10, the Y direction may be the first direction, the X direction may be the second direction, and the first direction and the second direction may be perpendicular to each other. A plane formed by the first direction and the second direction may be parallel to or coincident with the plane of the display panel.

When the number of the common power signal lines 501 in the display panel is larger, the resistance of the common power signal lines 501 may be lower, the voltage drop between different positions in the display panel may be smaller, and the uniformity of the display panel may be better. In some embodiments of the present disclosure, one common power signal line 501 may be provided in each pixel driving circuit group 300 as shown in FIG. 9, thereby greatly improving the uniformity of the display panel. In some other embodiments of the present disclosure, one common power signal line 501 may be provided at every interval of N1 pixel driving circuit groups 300. When N1 is smaller, the uniformity of the display panel may be better. In one embodiment shown in FIG. 10, N1 may be exemplarily set to 1, that is, every other pixel driving circuit group 300 may be provided with one common power signal line 501, to improve the display uniformity of the display panel.

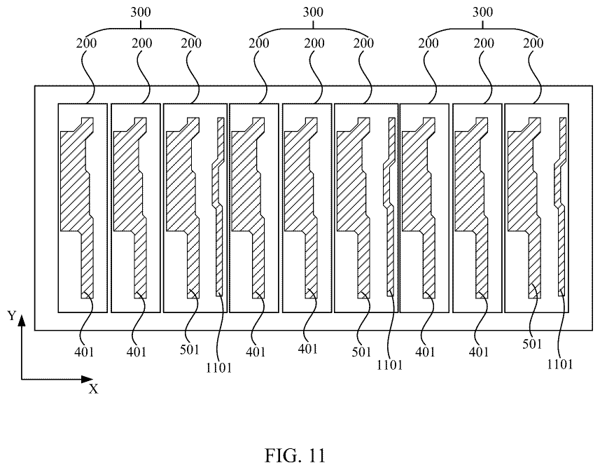

In some embodiments shown in FIG. 11 which is a top view of a film layer structure of another display panel, at least three pixel driving circuits 200 may form one pixel driving circuit group 300. Different pixel driving circuits 200 in one same pixel driving circuit group 300 may be electrically connected to light-emitting elements of different colors respectively. The first conductor layer may further include the first reference power signal lines 1101, and the first reference power signal lines 1101 may be electrically connected to the pixel driving circuits 200. The first reference power signal line 1101, the second power signal lines 402 and the first power signal lines 401 may all extend along the first direction. Along the second direction, one first reference power signal line 1101 may be disposed at every interval of N2 pixel driving circuit groups 300, where N2 is an integer larger than or equal to 0 and the second direction intersects the first direction.

The first reference power signal lines 1101 may be signal lines used to provide reference power signals to the pixel driving circuits 200, such as the VREF signal lines in FIG. 1 (including at least one of the VREF1 signal lines and the VREF2 signal lines). The Y direction in FIG. 11 may be the first direction, and the second direction and the first direction may be perpendicular to each other. A plane formed by the first direction and the second direction may be parallel to or coincident with the plane where the display panel is located. Multiple pixel driving circuit groups 300 may be arranged in an array along the second direction. In some embodiments, one first reference power signal line 1101 may be provided for every N2 pixel driving circuit groups 300 in the second direction, and the first reference power signal line 1101 may electrically connect the pixel driving circuits 200 in each pixel driving circuit group 300. In one embodiment shown in FIG. 11, N2 may be set to 0 for example, that is, each pixel driving circuit group 300 may be provided with one first reference power signal line 1101. In various embodiments of the present disclosure, N2 may be any positive integer larger than or equal to 0. In one embodiment shown in FIG. 11, the line shape of the first reference power signal lines 1101 may be different from the line shape of the second power signal lines 402 and the line shape of the first power signal lines 401. Therefore, in the present embodiment, the voltage drop of the reference power signals at different positions in the display panel may be reduced by providing the first reference power signal lines 1101, improving the uniformity of the display panel.

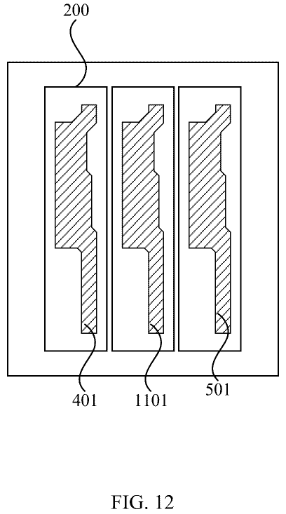

In some embodiments shown in FIG. 12 which is a top view of a film layer structure of another display panel, the second power signal lines may further include the first reference power signal lines 1101. The first reference power signal lines 1101 may be electrically connected to the pixel driving circuits 200.

In some embodiments, the space in the display panel may be tight and there may be not enough space in the display panel to additionally provide the first reference power signal lines 1101. In the present embodiment, the first reference power signal lines 1101 may be provided based on the second power signal lines 402. The line shape of the first reference power signal lines 1101 may be substantially the same as the line shape of the first power signal lines 401. That is, in the present embodiment, part of the signal lines serving as the first power signal lines 401 may be changed to serve as the first reference power signal lines 1101, thereby improving the display uniformity of the display panel without increasing the number of signal lines in the display panel, which is conducive to reducing the pitches of the display panel and improving the PPI of the display panel.

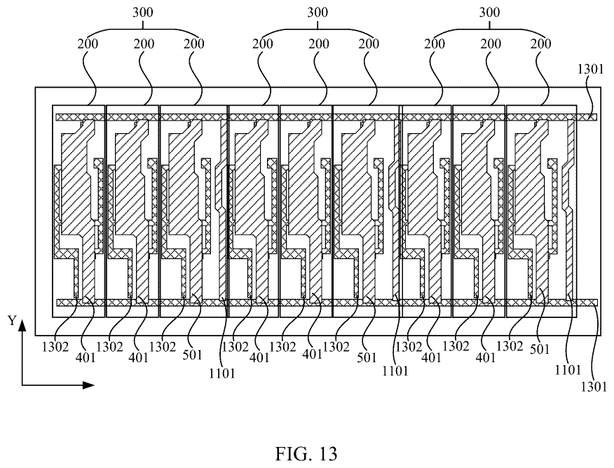

In some embodiments shown in FIG. 13 which is a top view of a film layer structure of another display panel, the display panel may further include an active layer, and the active layer may include the second reference power signal lines 1301. The second reference power signal lines 1301 may be electrically connected to the first reference power signal lines 1101.

The second reference power signal lines 1301 may be signal lines used to provide a reference power signal to the pixel driving circuits 200, such as the VREF signal lines in FIG. 1 (including at least one of the VREF1 signal lines and the VREF2 signal lines). The active layer may be made of semiconductor materials, such as low-temperature polysilicon or indium gallium zinc oxide. In this embodiment, signal lines for transmitting the reference power signal may be prepared based on the active layer as the second reference power signal line 1301, and the second reference power signal lines 1301 prepared based on the active layer may be conductorized. 1302 represents a conductorized connection line between an active area of a transistor and the transistor in one pixel driving circuit.

In the direction perpendicular to the plane of the display panel, the second reference power signal lines 1301 and the first reference power signal lines 1101 may be located on different layers. In one embodiment of the present disclosure, the first reference power signal lines 1101 and the second reference power signal lines 1301 may at least partially overlap in the direction perpendicular to the plane of the display panel, and the overlapping areas may be electrically connected to the second reference power signal lines 1301 through via holes. The extension direction of the first reference power signal lines 1101 and the extending direction of the second reference power signal lines 1301 may be different. For example, in one embodiment, the first reference power signal lines 1101 may extend along the first direction Y, and the second reference power signal lines 1301 may extend along the second direction X.

In one embodiment shown in FIG. 13, the line shape of the first reference power signal lines 1101 may be different from the line shape of the first power signal lines 401.

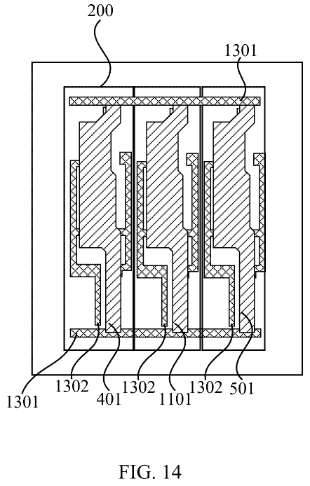

In one embodiment shown in FIG. 14 which is a top view of a film layer structure of another display panel, the line shape of the first reference power signal lines 1101 may be substantially similar as the line shape of the first power signal lines 401.

In the embodiments shown in FIG. 13 and FIG. 14, since the second reference power signal lines 1301 are electrically connected to the first reference power signal lines 1101, the second reference power signal lines 1301 may reduce the resistance of the first reference power signal lines 1101, thereby reducing the voltage drop of the reference power signals in the first reference power signal lines 1101 at different positions in the display panel and improving the display uniformity of the display panel.

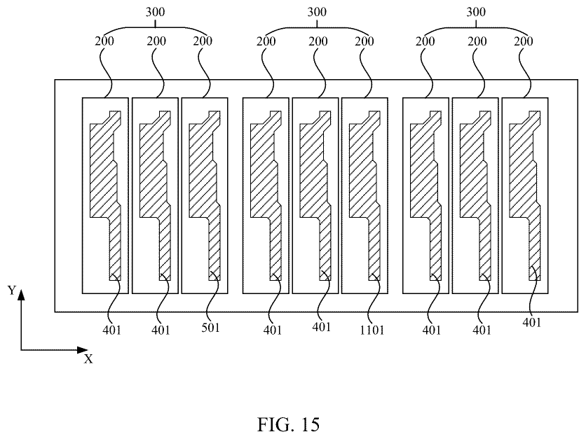

In some embodiments shown in FIG. 15 which is a top view of a film layer structure of another display panel, at least three pixel driving circuits 200 may form one pixel driving circuit group 300. Different pixel driving circuits 200 in one same pixel driving circuit group 300 may be electrically connected to light-emitting elements of different colors respectively. In the direction perpendicular to the plane of the base substrate 100, different pixel driving circuits 200 in one same pixel driving circuit group 300 may respectively overlap with different power signal lines. Among the at least three power signal lines corresponding to one same pixel driving circuit group 300, at least one power signal line may serve as the first power signal line 401, and at least another power signal line may serve as the first power signal line 401, the common power signal line 501, or the first reference power signal line 1101 with substantially the same line shape.

In the embodiment shown in FIG. 15, for example, the pixel driving circuit groups 300 and the pixel driving circuits 200 in the pixel driving circuit groups 300 may be arranged in an array along the X direction. Every three pixel driving circuits 200 may form one pixel driving circuit group 300. Along the X direction, the pixel driving circuits 200 in each pixel driving circuit group 300 may be electrically connected to a red light-emitting element, a green light-emitting element, and a blue light-emitting element in sequence. The electrical connection relationships are not shown in FIG. 15.

In one embodiment shown in FIG. 15, as an example, along the X direction, the third power signal line corresponding to the first pixel driving circuit group 300 may be the common power signal line 501, the third power signal line corresponding to the second pixel driving circuit group 300 may be the first reference power signal line 1101, the third power signal line corresponding to the third pixel driving circuit group 300 may be the first power signal line 401, and all other power signal lines may be the first power signal lines 401. In some other embodiments, the second and third power signal lines corresponding to the first pixel driving circuit group 300 may be set as the common power signal lines 501, the second and third power signal lines corresponding to the second pixel driving circuit group 300 may be set as the first reference power signal lines 1101, the second and third power signal lines corresponding to the third pixel driving circuit group 300 may be set as the first power signal lines 401, and all other power signal lines may be set as the first power signal lines 401. In some other embodiments, other suitable arrangement manners may be adopted and will not be described in detail.

In these embodiments, the number of common power signal lines 501 and first reference power signal lines 1101 in the display panel may be increased without increasing the number of wirings in the display panel, thereby improving the uniformity of the display panel. The pitches of the display panel may be also reduced and the PPI of the display panel may be increased.

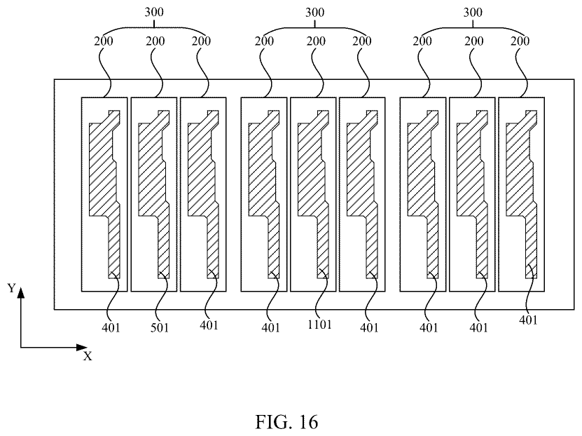

In some embodiments shown in FIG. 16 which is a top view of a film layer structure of another display panel, the second power signal lines 402 and the first power signal lines 401 may extend along the first direction. For the three pixel driving circuit groups 300 adjacent along the second direction, at least two power signal lines among the at least three power signal lines corresponding to each pixel driving circuit group 300 may be set as the first power signal lines 401, and at least another power signal line configured in each of the three pixel driving circuit groups 300 may be set as the common power signal line 501, the first reference power signal line 1101, or the first power signal line 401, respectively. The second direction may intersect the first direction.

In FIG. 16, the Y direction may be the first direction, and the second direction and the first direction may be perpendicular to each other. A plane formed by the first direction and the second direction may be parallel to the plane where the display panel is located, or may coincide with the plane where the display panel is located. Along the second direction, the third power signal line corresponding to the first pixel driving circuit group 300 may be the common power signal line 501, the third power signal line corresponding to the second pixel driving circuit group 300 may be the first reference power signal line 1101, the third power signal line corresponding to the third pixel driving circuit group 300 may be the first power signal line 401, and all other power signal lines may be the first power signal lines 401. Therefore, the uniformity of the display panel may be improved, the pitches of the display panel may be also reduced and the PPI of the display panel may be increased. Further, since the number of the first power signal lines 401 in the display panel is ensured, insufficient power of the first power signal in the first power signal lines 401 in the display panel may be prevented from affecting the display effect of the display panel.

In one embodiment shown in FIG. 15, along the second direction, among the at least three power signal lines corresponding to each pixel driving circuit group 300, at least two adjacent power signal lines may be set as the first power signal lines 401, and at least another power signal line at the edge may be set as the common power signal line 501, the first reference power signal line 1101, or the first power signal line 401.

In one embodiment shown in FIG. 16, along the second direction, among the at least three power signal lines corresponding to each pixel driving circuit group 300, at least two alternating power signal lines may be set as the first power signal lines 401, and at least another power signal line in the middle may be set as the common power signal line 501, the first reference power signal line 1101, or the first power signal line 401.

In one embodiment shown in FIG. 15, the first one and the second one of the power signal lines corresponding to each of the first pixel driving circuit group 300, the second pixel driving circuit group 300, and the third pixel driving circuit group 300 may be set as the first power signal lines 401. In one embodiment shown in FIG. 16, the first one and the third one of the power signal lines corresponding to each of the first pixel driving circuit group 300, the second pixel driving circuit group 300, and the third pixel driving circuit group 300 may be set as the first power signal lines 401. In the present disclosure, different arrangement manners of the signal lines may be adopted based on different situations to increase the flexibility of signal line settings. Furthermore, the same wiring method may be used between different pixel driving circuit groups 300. For example, among the three power signal lines corresponding to each pixel driving circuit group 300, the same signal line arrangement manner may be adopted. Therefore, difficulty in wiring and difficulty in drawing the layout used to prepare the signal lines may be reduced.

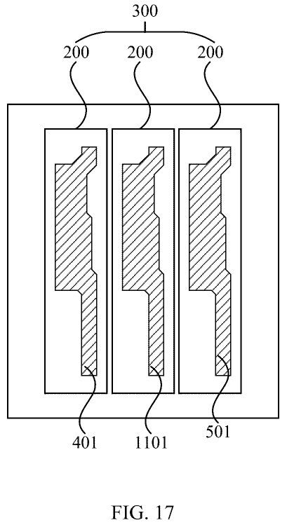

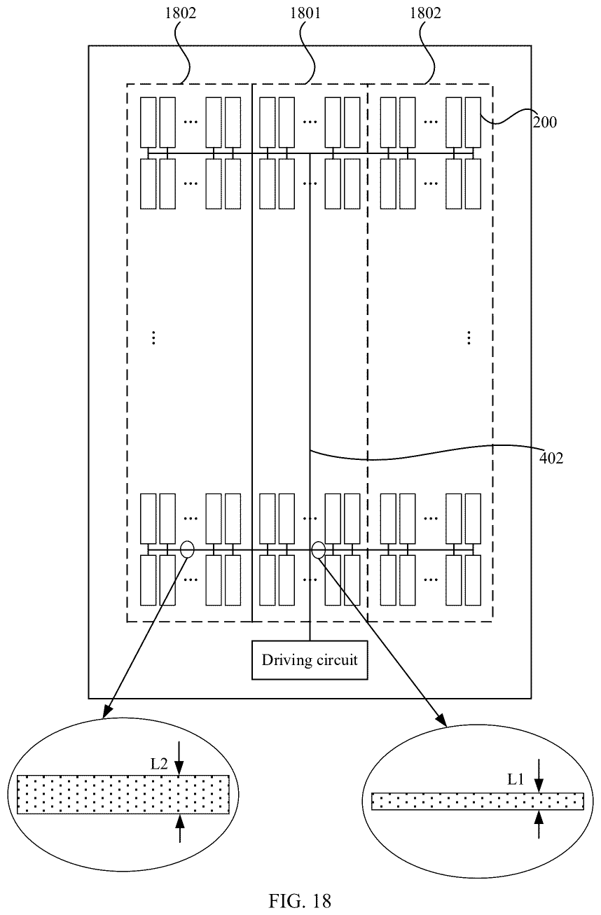

In some embodiments shown in FIG. 17 which is a top view of a film layer structure of another display panel, the at least three power signal lines corresponding to one same pixel driving circuit group 300 may include one first power signal line 401, one common power signal line 501 and one first reference power signal line 1101.

In this embodiment, the first power signal line 401, the common power signal line 501 and the first reference power signal line 1101 may be simultaneously provided in one same pixel driving circuit group 300. Further, the first power signal line 401, the common power signal line 501 and the first reference power signal line 1101 may have substantially the same line shape. Therefore, the number of the first reference power signal lines 1101 and the common power signal lines 501 in the display panel may be further increased, thereby further reducing the voltage drop at different locations in the display panel and improving the uniformity of the display panel. In one embodiment shown in FIG. 17, for example, among the at least three power signal lines in one pixel driving circuit group 300, the first one may be set as the first reference power signal line 1101, the second one may be set as the common power signal line 501, and the third one may be set as the first reference power signal line 1101. In some other embodiments, the ordering method of the first power signal line 401, the common power signal line 501 and the first reference power signal line 1101 in one pixel driving circuit group 300 may be flexibly set, and will not be described again here.

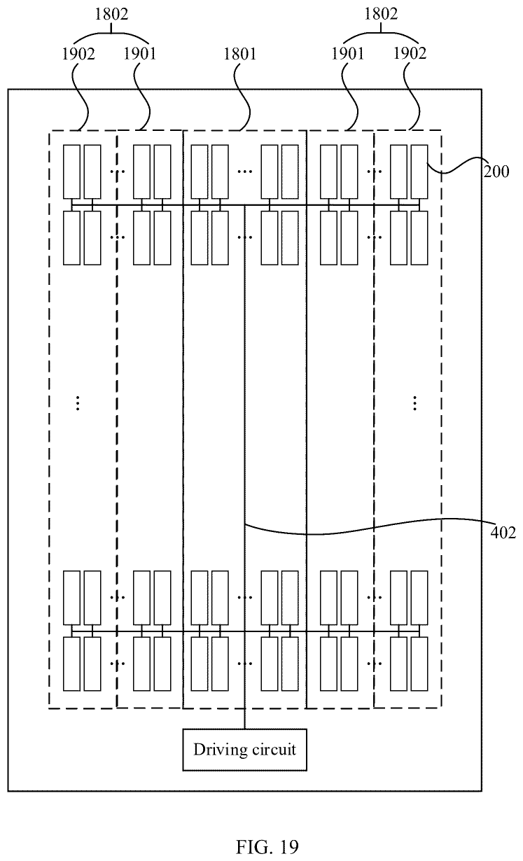

In some embodiments shown in FIG. 18 which is a structural diagram of a display panel, the display panel may include a central display area 1801 and an edge display area 1802 located on at least one side of the central display area 1801. The density of the second power signal lines 402 in the central display area 1801 may be smaller than or equal to the density of the second power signal lines 02 in the edge display area 1802, and/or, the line width of the second power signal lines 402 in the central display area 1801 may be smaller than or equal to the line width of the second power signal lines 402 in the edge display area 1802.

There are certain differences in the voltage drop at different positions in the display panel. When the second power signal lines 402 transmit signals from the bottom of the display panel to the display area of the display panel (including the central display area 1801 and the edge display area 1802), the voltage drop in the central display area 1801 may be smaller than the voltage drop in the edge display area 1802. In the present embodiment, the voltage drop in the central display area 1801 and the edge display area 1802 may be compensated. The compensation effect of the voltage drop in the edge display area 1802 may be better, and the compensation effect of the voltage drop in the central display area 1801 may be smaller, such that the electrical signals received by the pixel driving circuits 200 corresponding to the central display area 1801 and the pixel driving circuits 200 corresponding to the edge display area 1802 may have same or at least close voltage drop, thereby improving the display uniformity of the display panel.

In one embodiment, in the display panel, the density of the second power signal lines 402 in the central display area 1801 may be smaller than or equal to the density of the second power signal lines 02 in the edge display area 1802, and/or, the line width of the second power signal lines 402 in the central display area 1801 may be smaller than or equal to the line width of the second power signal lines 402 in the edge display area 1802. The density of the second power signal lines 402 may represent the number of the second power signal lines 402 within a unit area. The line width of the second power signal lines 402 may represent the width perpendicular to the extension direction of the second power signal lines 402. For example, the line width of the second power signal lines 402 in the central display area 1801 in FIG. 18 is L1, and the line width of the second power signal line s402 in the edge display area 1802 is L2, L2>L1. Since the density of the second power signal lines 402 in the central display area 1801 is smaller, the resistance may be larger. The density of the second power signal lines 402 in the edge display area 1802 may be larger, therefore, the resistance may be smaller. Since the line width of the second power signal lines 402 in the central display area 1801 is small, the resistance may be larger. The line width of the second power signal lines 402 in the edge display area 1802 may be larger, therefore, the resistance may be smaller. Correspondingly, the compensation effect of the voltage drop in the edge display area 1802 may be better, and the compensation effect of the voltage drop in the central display area 1801 may be smaller, thereby improving the display uniformity of the display panel.

In some embodiments shown in FIG. 19 which is a structural diagram of a display panel, each edge display area 1802 may include a first sub-display area 1901 and a second sub-display area 1902, and the first sub-display area 1901 may be located between the second sub-display area 1902 and the central display area 1801. The density of the second power signal lines 402 in the first sub-display area 1901 may be smaller than or equal to the density of the second power signal lines 402 in the second sub-display area 1902; and/or the line width of the second power signal lines 402 in the first sub-display area 1901 may be smaller than or equal to the line width of the second power signal lines 402 in the second sub-display area 1902.

As shown in FIG. 19, in the edge display area 1802, there may be also certain differences in the voltage drop at different locations. In this embodiment, the edge display area 1802 may be divided into the first sub-display area 1901 and the second sub-display area 1902, and the first sub-display area 1901 may be closer to the central display area 1801. The voltage drop in the first sub-display area 1901 may be smaller than the voltage drop in the second sub-display area 1902. In this embodiment, the density of the second power signal lines 402 in the first sub-display area 1901 may be set to be smaller than or equal to the density of the second power signal lines 402 in the second sub-display area 1902, and/or, the line width of the second power signal lines 402 in the first sub-display area 1901 may be smaller than or equal to the line width of the second power signal lines 402 in the second sub-display area 1902. Based on the same principle as the above-mentioned embodiment of FIG. 18, the display uniformity of the display panel may be improved.

In some other embodiments, the display panel may be divided into more display areas. The density of the second power signal lines 402 in a display area farther from the central area may be larger, and/or, the line width of the second power signal lines 402 in a display area farther from the central area may be larger, to improve the display uniformity of the display panel.

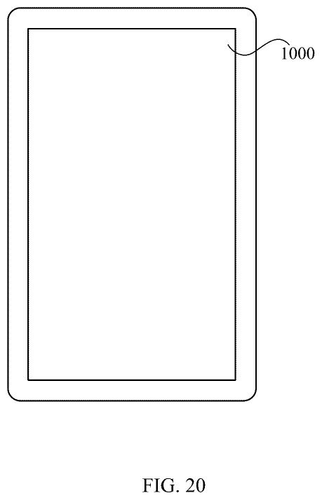

The present disclosure also provides a display device. In one embodiment shown in FIG. 20, the display device may include a display panel 1000 provided by various embodiments of the present disclosure. The display device provided by the present disclosure may have similar advantages as the display panel provided by various embodiments of the present disclosure.

In various embodiments, the display device may be, but is not limited to, a cell phone, a tablet, a vehicle computer, a smart wearable device with a display function, or another structural component with a display function. The present disclosure has no limit on this.

In the present disclosure, relational terms such as “first” and “second” are only used to distinguish one entity or operation from another entity or operation, and do not necessarily require or imply that there is a relationship between these entities or operations. There is no such actual relationship or sequence. Furthermore, the terms “comprises”, “include”, or any other variations thereof are intended to cover a non-exclusive inclusion such that a process, method, article, or apparatus that includes a list of elements includes not only those elements, but also those not expressly listed, or elements inherent to the process, method, article or equipment. Without further limitation, an element defined by the statement “comprises a . . . ” does not exclude the presence of additional identical elements in a process, method, article, or apparatus that includes the stated element.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

1. A display panel, comprising:
a substrate plate;
light-emitting elements and pixel driving circuits, wherein the pixel driving circuits are electrically connected to the light-emitting elements;
first power signal lines electrically connected to the pixel driving circuits; and
second power signal lines, wherein the second power signal lines and the first power signal lines are located in a first conductor layer and have substantially same line shapes.

2. The display panel according to claim 1, wherein:
the second power signal lines at least include common power signal lines, and the common power signal lines are electrically connected to the light-emitting elements.

3. The display panel according to claim 2, wherein:
at least three pixel driving circuits form a pixel driving circuit group;
different pixel driving circuits in one same pixel driving circuit group are electrically connected to the light-emitting elements of different colors respectively;
along a direction perpendicular to a plane where the substrate plate is located, different pixel driving circuits in one same pixel driving circuit group overlap with different power signal lines respectively; and
among at least three power signal lines corresponding to one same pixel driving circuit group, at least one power signal line is set as the first power signal lines, and at least one other power signal line is set as the common power signal line.

4. The display panel according to claim 3, wherein:
the power signal lines extend along a first direction; and
among the at least three power signal lines corresponding to one same pixel driving circuit group, at least two adjacent power signal lines along a second direction are set as the first power signal lines, and at least one other power signal line is set as the common power signal lines; or
among the at least three power signal lines corresponding to one same pixel driving circuit group, at least one power signal line is set as the common power signal line and is located between other two power signal lines that are set as the first power signal lines,
wherein:
the second direction intersects the first direction.

5. The display panel according to claim 2, wherein:
at least three pixel driving circuits form a pixel driving circuit group;
different pixel driving circuits in one same pixel driving circuit group are electrically connected to the light-emitting elements of different colors respectively;
the first power signal lines and the common power signal lines extend along a first direction;
along a second direction, each pixel driving circuit group is provided with one common power signal line, or one common power signal line is provided at an interval of every N1 pixel circuit groups, wherein N1 is an integer larger than 0 and the second direction intersects the first direction.

6. The display panel according to claim 2, wherein:
at least three pixel driving circuits form a pixel driving circuit group;
different pixel driving circuits in one same pixel driving circuit group are electrically connected to the light-emitting elements of different colors respectively;
the first conductor layer also includes first reference power signal lines;
the first reference power signal lines are electrically connected to the pixel driving circuits;
the first reference power signal lines, the second power signal lines and the first power signal lines all extend along a first direction;
along a second direction, one first reference power signal line is provided at an interval of every N2 pixel driving circuit groups, wherein: N2 is an integer larger than or equal to 0, and the second direction intersects the first direction.

7. The display panel according to claim 2, wherein:
the second power signal lines further include first reference power signal lines, and the first reference power signal lines are electrically connected to the pixel driving circuits.

8. The display panel according to claim 6, further including an active layer, wherein:
the active layer includes second reference power signal lines; and
the second reference power signal lines are electrically connected to the first reference power signal lines.

9. The display panel according to claim 7, wherein:
at least three pixel driving circuits form a pixel driving circuit group;
different pixel driving circuits in one same pixel driving circuit group are electrically connected to the light-emitting elements of different colors respectively;
along a direction perpendicular to a plane where the substrate plate is located, different pixel driving circuits in one same pixel driving circuit group overlap different power signal lines respectively; and
among the at least three power signal lines corresponding to one same pixel driving circuit group, at least one power signal line is set as the first power signal line, and at least another power signal line is set as the first power signal line, the common power signal line, or the first reference power signal line.

10. The display panel according to claim 9, wherein:
the second power signal lines and the first power signal lines extend along a first direction;
among the three pixel driving circuit groups adjacent along a second direction, at least two of the at least three power signal lines corresponding to each of the pixel driving circuit groups are set as the first power signal lines, another power signal line of the at least three power signal lines corresponding to each of the pixel driving circuit groups is set as the common power signal line, the first reference power signal line, and the first power signal line respectively; and
the second direction intersects the first direction.

11. The display panel according to claim 10, wherein, along the second direction, among the at least three power signal lines configured in each pixel driving circuit group:
at least two adjacent power signal lines are set as the first power signal lines, and at least one power signal line at the edge is set as the first power signal line, the common power signal line or the first reference power signal line; or
two alternate power signal lines are set as the first power signal lines, and at least one power signal line in the middle is set as the first power signal line, the common power signal line or the first reference power signal line.

12. The display panel according to claim 9, wherein:
the at least three power signal lines corresponding to one same pixel driving circuit group include the first power signal lines, the common power signal lines, and the first reference power signal lines.

13. The display panel according to claim 1, wherein:
the display panel has a central display area and an edge display area located on at least one side of the central display area;
a density of the second power signal lines in the central display area is smaller than or equal to a density of the second power signal lines in the edge display area; and/or, a line width of the second power signal lines in the central display area is smaller than or equal to a line width of the second power signal lines in the edge display area.

14. The display panel according to claim 13, wherein:
the edge display area includes a first sub-display area and a second sub-display area, and the first sub-display area is located between the second sub-display area and the central display area; and
a density of the second power signal lines in the first sub-display area is smaller than or equal to a density of the second power signal lines in the second sub-display area; and/or, a line width of the second power signal lines in the first sub-display area is smaller than or equal to a line width of the second power signal lines in the second sub-display area.

15. A display device comprising a display panel, wherein:
the display panel includes:
a substrate plate;
light-emitting elements and pixel driving circuits, wherein the pixel driving circuits are electrically connected to the light-emitting elements;
first power signal lines electrically connected to the pixel driving circuits; and
second power signal lines, wherein the second power signal lines and the first power signal lines are located in a first conductor layer and have substantially same line shapes.

16. The display device according to claim 15, wherein:
the second power signal lines at least include common power signal lines, and the common power signal lines are electrically connected to the light-emitting elements.

17. The display device according to claim 16, wherein:
at least three pixel driving circuits form a pixel driving circuit group;
different pixel driving circuits in one same pixel driving circuit group are electrically connected to the light-emitting elements of different colors respectively;
along a direction perpendicular to a plane where the substrate plate is located, different pixel driving circuits in one same pixel driving circuit group overlap with different power signal lines respectively; and
among at least three power signal lines corresponding to one same pixel driving circuit group, at least one power signal line is set as the first power signal lines, and at least one other power signal line is set as the common power signal line.

18. The display device according to claim 17, wherein:
the power signal lines extend along a first direction; and
among the at least three power signal lines corresponding to one same pixel driving circuit group, at least two adjacent power signal lines along a second direction are set as the first power signal lines, and at least one other power signal line is set as the common power signal lines; or
among the at least three power signal lines corresponding to one same pixel driving circuit group, at least one power signal line is set as the common power signal line and is located between other two power signal lines that are set as the first power signal lines,
wherein:
the second direction intersects the first direction.

19. The display device according to claim 16, wherein:
at least three pixel driving circuits form a pixel driving circuit group;
different pixel driving circuits in one same pixel driving circuit group are electrically connected to the light-emitting elements of different colors respectively;
the first conductor layer also includes first reference power signal lines;
the first reference power signal lines are electrically connected to the pixel driving circuits;
the first reference power signal lines, the second power signal lines and the first power signal lines all extend along a first direction;
along a second direction, one first reference power signal line is provided at an interval of every N2 pixel driving circuit groups, wherein: N2 is an integer larger than or equal to 0, and the second direction intersects the first direction.

20. The display panel according to claim 7, further including an active layer, wherein:
the active layer includes second reference power signal lines; and
the second reference power signal lines are electrically connected to the first reference power signal lines.
